(19) United States
(12) Patent Application Publication
(10) Pub. No.: US 2006/0285618 A1
(43) Pub. Date: Dec. 21, 2006

(54) Adaptive phase recovery

(76) Inventor: Ehud Shoor, Nesher (IL)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/158,515

(22) Filed: Jun. 21, 2005

(51) Int. Cl. H03D 3/24

(52) U.S. Cl. 375/373

(57) ABSTRACT

In some embodiments, an adaptive phase recovery system is provided that involves monitoring a phase error polarity in a phase recovery system, and increasing its bandwidth when the phase error polarity fails to change within a specified limit. Other embodiments are described and/or otherwise claimed herein.

### TECHNICAL FIELD

Embodiments disclosed herein relate generally to integrated circuit (“IC”) devices and in particular to phase recovery circuits.

### BACKGROUND

In communications systems, phase (or timing) recovery systems may be used to track (or recover) phase information from an input bit stream signal, for example, in clock and data recovery (CDR) applications. In a receiver, for example, a phase recovery circuit may be used to track the phase of an incoming data bit stream signal. Setting an appropriate tracking bandwidth can be an important factor for the performance of such a circuit.

Unfortunately, there is a tradeoff between system response (which is proportional to system bandwidth) and noise rejection capability (which is inversely proportional to system bandwidth). This is indicated in FIG. 1, which shows an input phase signal and recovery phase signals for two cases: a low system bandwidth and a higher system bandwidth. With the low bandwidth case, noise rejection is good, but system response is poor. As indicated in the figure, when the input phase is stable, the system response is sufficient to track the input phase. However, when the input phase changes at a faster rate, the system is unable to track it resulting in a persistent, fairly large phase error between the two signals. With the high bandwidth case, this is not a problem. the system is able to track the input phase, even when it changes at a fairly rapid rate. Unfortunately, its noise rejection may not be desirable, especially when the input phase is stable and a high bandwidth may not even be needed.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 shows phase signals for a conventional phase recovery system for both a low and high bandwidth case.

FIG. 2 is a state flow diagram of an adaptive phase recovery routine according to some embodiments.

FIG. 3 is a block diagram of a phase recovery system in accordance with some embodiments.

FIG. 4 shows phase signals for the system of FIG. 3 illustrating adaptive adjustment of system bandwidth settings.

FIG. 5 is a schematic block diagram of an adaptive bandwidth control circuit suitable for use in the system of FIG. 3 according to some embodiments.

FIG. 6 is a block diagram of a computer system with at least one phase recovery system in accordance with some embodiments.

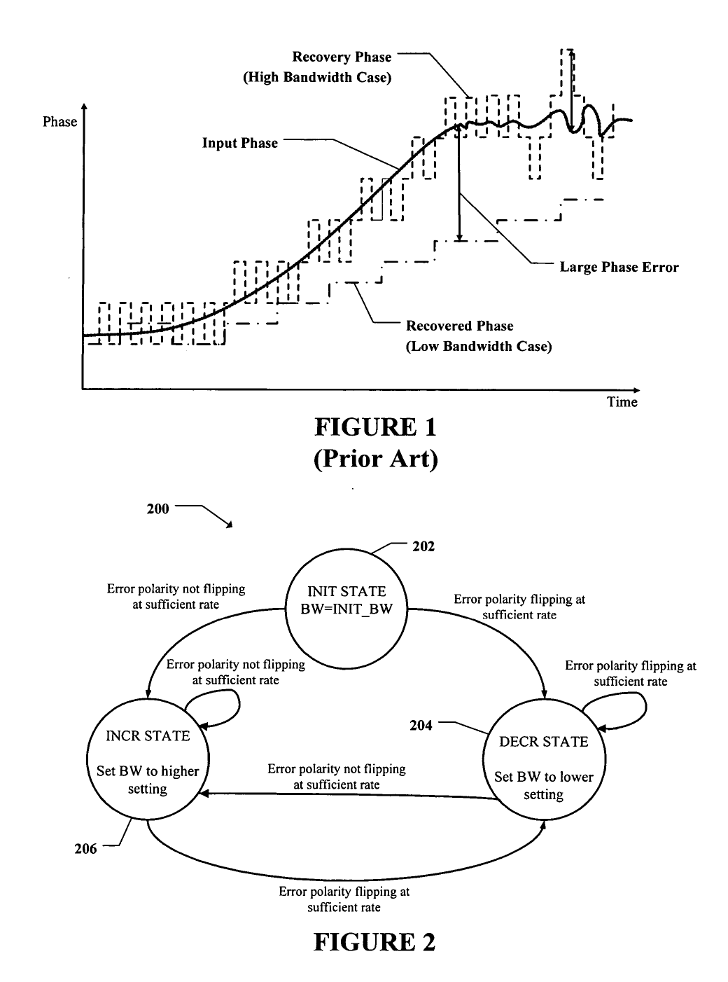

### DETAILED DESCRIPTION

Some embodiments discussed herein employ adaptive approaches to dynamically adjust bandwidth in a phase recovery system. In some embodiments, the bandwidth is adjusted based on the phase error between the incoming and recovered signals, which allows it to adapt to the specific jitter (phase change) properties of the incoming signal independent of system specific characteristics.

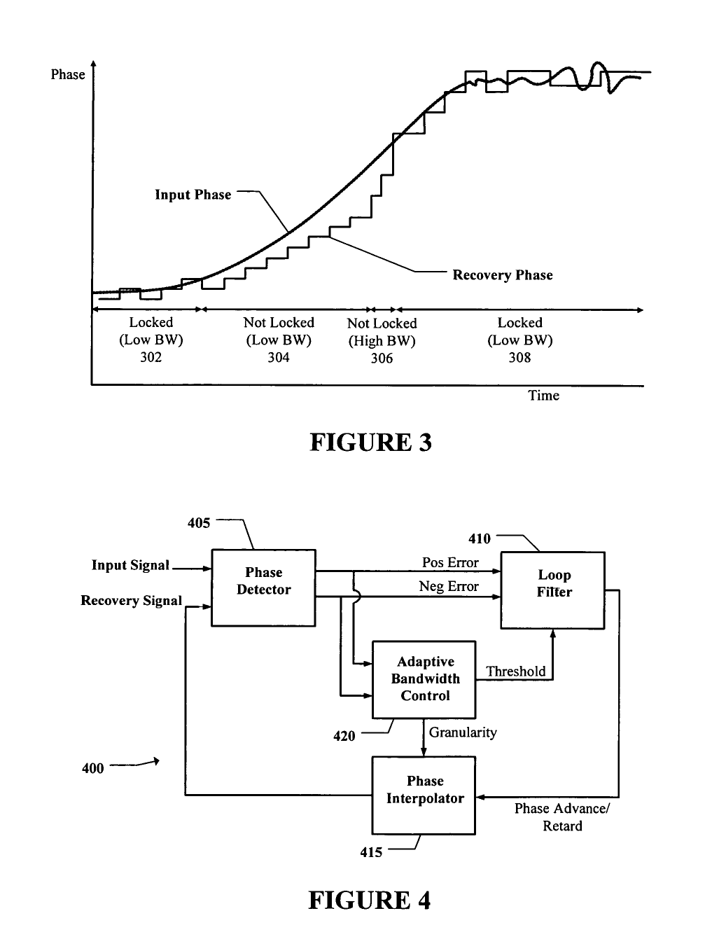

With reference to FIGS. 2 and 3, a general approach to adaptive phase recovery according to some embodiments is shown. FIG. 2 shows a state flow diagram 200 for performing adaptive phase recovery, and FIG. 3 graphically shows recovery and input phase signals illustrating phase recovery for different input phase stabilities. This approach may be implemented independent of a particularly utilized phase recovery architecture.

State diagram 200 generally comprises an initial state 202, a decrement state 204, and an increment state 206. At the initial state (start of system), an initial recovery system bandwidth is set. The phase difference (phase error) between the input and recovery signal phases is monitored, and the time (e.g., number of clock counts) between changes in phase error polarity is tracked. If the phase error polarity changes at a sufficient rate (e.g., before a count setting is reached), then the routine progresses to the decrement state 204, and the system bandwidth is decremented to (or remains at) a lower bandwidth setting. (The rate of polarity flip can be used to indicate whether or not the system is “locked” to the input phase. If it changes at a sufficient rate, then the recovery signal, under proper conditions, can be assumed to approach super-imposing the input phase, which indicates that it is suitably tracking it.) In FIG. 3, this would correspond to locked modes 302 and 308. It remains in the decrement state 204 and continues to decrement (or maintain constant) the bandwidth until it reaches a lowest available bandwidth setting or until the polarity stops flipping at the sufficient rate, at which time the routine transitions to the increment state 206.

On the other hand, if from the initial state 202 the phase error polarity does not flip at the sufficient rate, then the routine transitions to the increment state 206 and increments (or maintains) the bandwidth to a higher, available setting. (In FIG. 3, a low to high bandwidth transition is indicated where the system goes from a not locked, low bandwidth at 304 to a not locked, high bandwidth at 306.) It stays in this state and continues to increment (or keep the same) the bandwidth until it reaches a highest available bandwidth setting or until it leaves the state (starts flipping at the sufficient rate). If the polarity starts to flip at the sufficient rate, the routine transitions to the decrement state 204. (This is indicated in FIG. 3 at 308, where the system is “locked on” once again.) Under steady state operation, the routine continues to transition between the decrement state 204 and increment state 206 based on the rate at which the polarity flips. In this way, a relatively low bandwidth can be employed when the input phase is stable, while a higher bandwidth can be used to sufficiently track input phase when the input phase changes at a faster rate.

With reference to FIG. 4, a phase recovery system 400 is shown. System 400 comprises a phase detector 405, a loop filter 410, a phase interpolator 415, and an adaptive bandwidth control (ABC) circuit 420, which may be used to perform the state flow routine 200. The phase detector 405 receives an input signal and a recovery signal and generates a phase error signal, which corresponds to the phase difference between the input and recovery signals. The depicted phase error signal comprises a positive error (Pos Error) signal and a negative error (Neg Error) signal coupled to the loop filter 410 and to the ABC circuit 420. The ABC circuit 420 is coupled to the loop filter 410 to provide it with a threshold adjustment signal. The loop filter 410 is also coupled to the phase interpolator 415 to provide it with a phase advance/retard signal to command it to increase, decrease, or maintain the phase of the recovery signal, which is coupled to the phase detector 405. The ABC circuit 420 is also coupled to the phase interpolator 415 to provide it with a granularity adjustment signal.

The Pos and Neg Error signals indicate whether or not the input phase is ahead of (greater than), behind (less than), or equal to the recovery phase. In some embodiments, the Pos Error signal is a digital signal that asserts (e.g., “1”) when the input phase is greater than the recovery phase and de-asserts (e.g., “0”) otherwise. Similarly, the Neg Error signal asserts when the recovery signal phase is greater than that of the input signal and de-asserts otherwise. (In some embodiments, both signals de-assert when the phases are equal or when phase information is not available, e.g., when a bit stream remains high or low for multiple cycles.)

In some embodiments, the loop filter 410 is implemented with a conventional accumulator topology to count (accumulate) Pos Error and Neg Error information against each other and asserts the advance/retard signal after a sufficient Pos Error or Neg Error count threshold is satisfied. In this way, it filters out noise that may otherwise assert the advance/retard signal in an unstable manner. It also provides design flexibility in attaining desired phase recovery system response characteristics. The loop filter threshold (count threshold) is set by the ABC circuit 420.

In some embodiments, the loop filter 410 is implemented with an up/down counter that increments when the Pos Error is asserted and decrements when the Neg Error is asserted. The filter threshold is determined based on a selected count that is used to assert the advance/retard signal. In some embodiments, the advance/retard signal comprises two signals, one for commanding a phase increase and the other for commanding phase decrease. The signals are coupled to the selected (based on threshold setting) counter output bit through suitable decode circuitry, which may be controlled by a sign bit in the counter. When the threshold is reached, depending on the sign of the count, either the advance or retard signal asserts to command the phase interpolator 415 to increase or decrease, respectively, the recovery signal phase.

The phase interpolator 415 may be implemented with any suitable circuit including a conventional phase interpolator or voltage controlled oscillator (VCO) circuit appropriately designed for granularity adjustment by the ABC circuit 420. The phase interpolator operates to increase (advance) the recovery signal phase in response to an advance command from the loop filter 410 and decreases (moves back) the recovery signal phase in response to a retard command from the loop filter 410. The amount of phase increase or decrease depends on a granularity (magnitude) setting, which is controlled by the granularity adjust signal from the ABC circuit 420.

The loop filter threshold and phase interpolator granularity settings determine the phase recovery system bandwidth. The bandwidth increases as the loop filter threshold decreases and/or when the granularity setting increases. Conversely, it is reduced when the loop filter threshold is increased and/or when the granularity is decreased. This is illustrated with the recovery signal in FIG. 3, which has relatively higher bandwidths at 304 and lower bandwidths at 302 and 306. The width of a recovery signal phase step is dictated by the loop filter threshold setting. The lower the threshold, the narrower the step and thus a higher bandwidth. The height of a recovery signal step is dictated by the granularity setting of the phase interpolator 415. The larger the setting, the larger the phase increment/decrement and thus, the higher the bandwidth.

In some embodiments, when a counter is used to implement the loop filter, the circuit is configured so that the count threshold can be adjusted from between 4 and 245. (For example, decoder circuitry, controlled by the threshold signal from the ABC circuit 420, could be used to select one of the counter outputs to be used for the advance/retard signal.) Likewise, in some embodiments, a phase interpolator 415 is used with four different phase increment/decrement settings: 6.25 pico-seconds, 12.5 pico-seconds, 25 pico-seconds., and 37.5 pico-seconds, one of which is selected by the granularity signal from the ABC circuit 420.

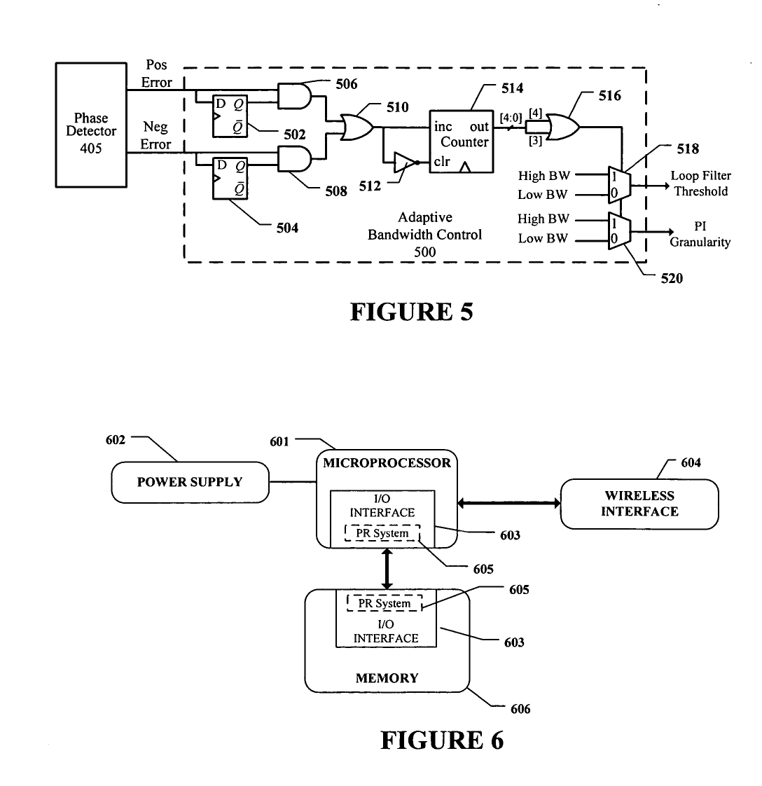

The ABC circuit 420 may be implemented with any suitable circuit to provide threshold adjust and/or granularity adjust signals to adaptively control phase recovery system bandwidth based on phase error. For example, an ABC circuit 420 could comprise any circuit suitable to perform a routine according to the state flow diagram of FIG. 2. FIG. 5 shows an exemplary ABC circuit 500 that may be used as an ABC circuit 420 in the system 400 of FIG. 4.

With reference to FIG. 5, ABC circuit 500, which has two bandwidth settings (High and Low), will now be described. Circuit 500 generally comprises flip-flops 502, 504, And gates 506, 508, Or gates 510, 516, inverter 512, counter 514, and multiplexers 518, 520, all coupled together as depicted. Flip-flops 502 and And gate 506 serve to identify when the Pos Error is asserted for two consecutive clock cycles. When the Pos Error is asserted (indicating that the input phase is ahead of the recovery phase) for two consecutive cycles, the output of And gate 506 asserts. Flip-flop 504 and And gate 508 operate similarly but with the Neg Error rather than the Pos Error signal. When the Neg Error signal is asserted for two consecutive cycles, the output of And gate 508 asserts.

Thus, when either And gate 506 or And gate 508 asserts, Or gate 510 asserts, which causes counter 514 to increment. On the other hand, the counter is cleared by inverter 512 if the Or gate output is de-asserted (when a change in polarity occurs). Thus, counter 514 counts (with a negative offset of 1) the number of consecutive clock cycles that the polarity stays the same (positive or negative). That is, if the polarity is the same for N cycles, then the count would be N−1.

In the depicted circuit, counter 514 is implemented with a 5-bit counter with output pins 3 and 4 serving as inputs to the Or gate 516. Thus, in this embodiment, when the count reaches eight (indicating that the phase error has been positive for 9 consecutive cycles or negative for 9 consecutive cycles), Or gate 516 asserts causing the multiplexers 518 and 520 to switch from the Low bandwidth to the High bandwidth settings for the loop filter threshold and phase interpolator granularity settings, respectively. On the other hand, if the count is less than eight (polarity flipping within 9 cycles), the Low bandwidth setting is selected.

With the use of different count triggers (output bit[s] to Or gate 516), different polarity flip-rate thresholds can be achieved along these lines, while the depicted circuit has just two bandwidth settings: High and Low, any reasonable number of different system bandwidth settings could be employed. With suitable decoding circuitry, different count triggers could be used to provide different loop filter and/or granularity combinations to achieve different desired system bandwidth settings.

In some embodiments, the count trigger(s) (flip-rate threshold) are adjustable, e.g., to enhance flexibility in setting bandwidth transition points for specific systems and/or for “on the fly” adjustment. Moreover, in some embodiments, circuitry is included to suitably maintain the counting when both Pos Error and Neg. Error are de-asserted. That is, if the error polarity is constant for a number of consecutive cycles and then multiple bits of like data arrive at an input signal (preventing a phase detector from assessing phase error), the ABC may have additional circuitry to override the de-assertion of Or gate 510 and maintain counter 514 counting.

Furthermore, it should be appreciated that particular circuit blocks have been disclosed as examples of suitable implementations, but embodiments of the invention are not so limited. For example, different conventional phase detector implementations (e.g., linear phase detector), phase interpolator, loop filter (if included) could be used. In addition, while in the described example, the ABC adjusts both filter threshold and phase granularity to control system bandwidth, it should be appreciated that just one or even none (if another parameter for controlling system bandwidth is available) of these parameters could be adjusted to control system bandwidth.

With reference to FIG. 6, one example of an application (timing recovery in one or more I/O interfaces in a computer system) for a phase recovery system disclosed herein is shown. (However, it should be appreciated that systems disclosed herein could generally be applied to a variety of timing recovery applications.) The depicted system generally comprises a processor 601 coupled to a power supply 602, a wireless interface 604, and memory 606. It is coupled to the power supply 602 to receive from it power when in operation. It is coupled to the wireless interface 604 and to the memory 606 with separate point-to-point links to communicate with the respective components. It, along with memory 606, includes an I/O interface 603, which includes a phase recovery system 605 in accordance with some embodiments of the invention.

It should be noted that the depicted system could be implemented in different forms. That is, it could be implemented in a single chip module, a circuit board, or a chassis having multiple circuit boards. Similarly, it could constitute one or more complete computers or alternatively, it could constitute a component useful within a computing system.

The invention is not limited to the embodiments described, but can be practiced with modification and alteration within the spirit and scope of the appended claims. For example, it should be appreciated that the present invention is applicable for use with all types of semiconductor integrated circuit (“IC”) chips. Examples of these IC chips include but are not limited to processors, controllers, chip set components, programmable logic arrays (PLA), memory chips, network chips, and the like.

Moreover, it should be appreciated that example sizes/models/values/ranges may have been given, although the present invention is not limited to the same. As manufacturing techniques (e.g., photolithography) mature over time, it is expected that devices of smaller size could be manufactured. In addition, well known power/ground and clock connections to IC chips and other components may or may not be shown within the FIGS. for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. A circuit, comprising:
a phase recovery system having an adjustable system bandwidth, the system comprising an adaptive bandwidth control circuit to adjust the system bandwidth based on a rate of polarity change of a phase error between an input signal and a system recovery signal.

2. The circuit of claim 1, in which the adaptive bandwidth control circuit is to increase the bandwidth when the rate of polarity change is below a predefined level.

3. The circuit of claim 1, in which the adaptive bandwidth control circuit is to adjust the system bandwidth between a plurality of discrete bandwidth settings.

4. The circuit of claim 3, in which the adaptive bandwidth control circuit is to adjust the system bandwidth between a high and a low bandwidth setting.

5. The circuit of claim 1, in which the adaptive bandwidth control circuit is to generate a threshold signal to adjust a response of a filter in the phase recovery system in order to adjust the system bandwidth.

6. The circuit of claim 5, in which the adaptive bandwidth control circuit is to generate a granularity signal to adjust a phase magnitude parameter.

7. The circuit of claim 6, in which the adaptive bandwidth control circuit is to generate the granularity signal to adjust a phase interpolator circuit.

8. The circuit of claim 1, in which the adaptive bandwidth control circuit comprises a counter to track the rate of polarity change.

9. The circuit of claim 1, in which the phase recovery system comprises a loop filter comprising a counter to accumulate phase error polarity information.

10. A method, comprising:
monitoring a phase error polarity in a phase recovery system having a system bandwidth; and
increasing the system bandwidth when the phase error polarity fails to change within a specified limit.

11. The method of claim 10, in which the bandwidth is increased when the phase error polarity stays the same for at least a predefined number of clock cycles.

12. The method of claim 10, in which increasing the system bandwidth comprises increasing the response of a filter in the system.

13. The method of claim 12, in which increasing the response of a filter comprises decreasing an accumulator threshold.

14. The method of claim 10, in which increasing the system bandwidth comprises increasing the granularity of a phase interpolator in the system.

15. The method of claim 10, in which the phase error polarity is based on the relative values of a positive and a negative phase error signal, which are based on a phase difference between an input signal and a system phase recovery signal.

16. The method of claim 10, in which monitoring a phase error polarity comprises counting the number of consecutive cycles in which the polarity does not change.

17. A system, comprising:
(a) a microprocessor having an I/O interface with a phase recovery system circuit comprising an adjustable system bandwidth, the system comprising an adaptive bandwidth control circuit to adjust the system bandwidth based on a rate of polarity change of a phase error between an input signal and a system recovery signal; and
(b) a power supply coupled to the microprocessor to supply it with power.

18. The system of claim 17, in which the power supply comprises a battery.

19. The system of claim 17, comprising a network interface including an antenna to link the microprocessor to a wireless device.
